(19) United States
(12) Patent Application Publication
(10) Pub. No.: US 2025/0056733 A1
(43) Pub. Date: Feb. 13, 2025

(54) MANUFACTURING METHOD FOR CONDUCTIVE SUBSTRATE

(71) Applicant: FUJIFILM Corporation, Tokyo (JP)

(72) Inventor: Akira ICHIKI, Kanagawa (JP)

(73) Assignee: FUJIFILM Corporation, Tokyo (JP)

(21) Appl. No.: 18/925,888

(22) Filed: Oct. 24, 2024

Related U.S. Application Data
(63) Continuation of application No. PCT/JP2023/015745, filed on Apr. 20, 2023.

(30) Foreign Application Priority Data
Apr. 28, 2022 (JP) 2022-075107

(51) Int. Cl. H05K 3/24; G06F 3/044

(52) U.S. Cl. CPC H05K 3/241; G06F 3/0446; G06F 2203/04103; H05K 2203/0723

(57) ABSTRACT

A manufacturing method for a conductive substrate having a conductive thin wire with a thin line width and excellent conductivity in which the intersection growing is suppressed. The manufacturing method includes a step of forming a mesh-shaped underlying silver pattern on a side of one surface of a base material by a photographic method, a step of disposing a resist film on the side of the surface of the base material on which the underlying silver pattern is formed, a step of exposing the resist film by irradiation of light from a side of a surface of the base material on which the underlying silver pattern is not formed, a step of developing the exposed resist film to form a resist pattern, and a step of performing a plating treatment using the underlying silver pattern as a seed layer to form a metal pattern on the underlying silver pattern.

### CROSS-REFERENCE TO RELATED APPLICATIONS

This application is a Continuation of PCT International Application No. PCT/JP2023/015745 filed on Apr. 20, 2023, which was published under PCT Article 21 (2) in Japanese, and which claims priority under 35 U.S.C. § 119 (a) to Japanese Patent Application No. 2022-075107 filed on Apr. 28, 2022. The above applications are hereby expressly incorporated by reference, in their entirety, into the present application.

### BACKGROUND OF THE INVENTION

### 1. Field of the Invention

The present invention relates to a manufacturing method for a conductive substrate.

### 2. Description of the Related Art

A base material having a conductive thin wire (a thin wire-shaped wire that exhibits conductivity) (hereinafter, also referred to as a “conductive substrate”) is widely used for various applications such as a touch panel, a solar cell, and an electroluminescence (EL) element. In particular, in recent years, the mounting rate of touch panels on mobile phones and mobile game devices has been increasing, and the demand for the conductive substrate for a capacitance type touch panel that makes multi-point detection possible is rapidly expanding.

The conductive thin wire can be formed by, for example, a semi-additive method including a step of providing a plating resist pattern for a metal wire pattern on the surface of the first metal layer using a negative tone photoresist, performing electroplating, peeling off the plating resist pattern, and then removing the first metal layer, as shown in JP2007-287953A.

### SUMMARY OF THE INVENTION

The present inventor has manufactured a conductive substrate having a conductive thin wire by using the method described in JP2007-287953A, and has found that, in a case of forming a plating resist pattern, intersection growing in which a line width of an opening portion of the plating resist pattern of a portion corresponding to an intersection portion of the conductive thin wire is thicker than a line width of a portion other than the intersection portion has occurred. A conductive thin wire has been formed using the above-described plating resist pattern in which the intersection growing has occurred, and the intersection growing has also occurred at the intersection portion in the formed conductive thin wire. Thus, it has been necessary to improve the conductive thin wire.

In addition, in the conductive substrate, it may be required that a line width of the conductive thin wire is thin and the conductivity of the conductive thin wire is excellent.

Therefore, an object of the present invention is to provide a manufacturing method for a conductive substrate, by which the conductive substrate having a conductive thin wire with a thin line width and excellent conductivity in which the intersection growing is suppressed can be manufactured.

The present inventors conducted a thorough investigation to achieve the objects, thereby completing the present invention. That is, the present inventors have found that the objects are achieved by the following configuration.

[1] A manufacturing method for a conductive substrate, comprising:
a step of forming a mesh-shaped underlying silver pattern on a side of one surface of a base material by a photographic method;
a step of disposing a resist film on the side of the surface of the base material on which the underlying silver pattern is formed;
a step of exposing the resist film by irradiation of light from a side of a surface of the base material on which the underlying silver pattern is not formed;
a step of developing the exposed resist film to form a resist pattern; and
a step of performing a plating treatment using the underlying silver pattern as a seed layer to form a metal pattern on the underlying silver pattern, thereby obtaining a conductive thin wire.

[2] The manufacturing method for a conductive substrate according to [1], in which an intersection growing ratio of the conductive thin wires is 1.0 to 1.5.

[3] The manufacturing method for a conductive substrate according to [1] or [2], in which a line width of the conductive thin wire is 3.0 μm or less.

[4] The manufacturing method for a conductive substrate according to any one of [1] to [3], in which a thickness of the underlying silver pattern is 1.0 μm or less.

[5] The manufacturing method for a conductive substrate according to any one of [1] to [4], in which a ratio of a height of the conductive thin wire to a line width of the conductive thin wire is 1.10 or more.

According to the present invention, a manufacturing method for a conductive substrate can be provided, by which the conductive substrate having a conductive thin wire with a thin line width and excellent conductivity in which the intersection growing is suppressed can be manufactured.

### BRIEF DESCRIPTION OF THE DRAWINGS

FIG. 1 is a plan view illustrating an embodiment of a mesh-shaped underlying silver pattern.

FIG. 2 is a diagram describing a resist film disposing step.

FIG. 3 is a diagram describing a resist film exposure step.

FIG. 4 is a diagram describing a resist film developing step.

FIG. 5 is a diagram describing a conductive thin wire forming step.

FIG. 6 is an enlarged plan view of an intersection part of a conductive thin wire for describing an intersection growing.

FIG. 7 is an enlarged plan view of an intersection part of a conductive thin wire for describing an intersection growing.

### DESCRIPTION OF THE PREFERRED EMBODIMENTS

Hereinafter, the present invention will be described in detail.

Description of configuration requirements described below may be made on the basis of representative embodiments of the present invention in some cases, but the present invention is not limited to such embodiments.

Hereinafter, the meaning of each description in the present specification will be described.

In the present specification, any numerical range expressed by using “to” means a range including the numerical values before and after the “to” as a lower limit value and an upper limit value, respectively.

In the present specification, in a case where there are two or more components corresponding to a certain component, the “content” of such a component means a total content of the two or more components.

In the present specification, “g” and “mg” represent “mass g” and “mass mg”, respectively.

In the present specification, “polymer” or “polymer compound” represents a compound having a weight-average molecular weight of 2,000 or higher. Here, the weight-average molecular weight is defined as a value measured by gel permeation chromatography (GPC) and calculated in terms of polystyrene.

In the present specification, unless specified otherwise, an angle represented by a specific numerical value and the description regarding an angle such as “parallel”, “perpendicular”, or “orthogonal” includes an error range that is generally allowable in the corresponding technical field.

An “organic group” in the present specification refers to a group including at least one carbon atom.

The manufacturing method for a conductive substrate according to the embodiment of the present invention includes a step of forming a mesh-shaped underlying silver pattern on a side of one surface of a base material by a photographic method (hereinafter, also referred to as an “underlying silver pattern forming step”), a step of disposing a resist film on the side of the surface of the base material on which the underlying silver pattern is formed (hereinafter, also referred to as a “resist film disposing step”), a step of exposing the resist film by irradiation of light from a side of a surface of the base material on which the underlying silver pattern is not formed (hereinafter, also referred to as a “resist film exposure step”), a step of developing the exposed resist film to form a resist pattern (hereinafter, also referred to as a “resist film developing step”), and a step of performing a plating treatment using the underlying silver pattern as a seed layer to form a metal pattern on the underlying silver pattern, thereby obtaining a conductive thin wire (hereinafter, also referred to as a “conductive thin wire forming step”).

According to the manufacturing method for a conductive substrate according to the embodiment of the present invention, a conductive substrate having a conductive thin wire with a thin line width and excellent conductivity in which the intersection growing is suppressed can be manufactured. A mechanism by which the conductive substrate having the above-described characteristics can be manufactured according to the present invention is not always clear, but the present inventor presumes as follows.

In the manufacturing method for a conductive substrate according to the embodiment of the present invention, first, in the underlying silver pattern forming step, a mesh-shaped underlying silver pattern is formed by a photographic method. In this case, since the photographic method is used, a mesh-shaped underlying silver pattern in which the contrast between the exposed portion and the non-exposed portion is likely to be formed and the intersection growing is suppressed can be formed. In addition, according to the photographic method, it is easy to form a underlying silver pattern having a thin line width.

In addition, in a case where the resist film exposure step is carried out next to the resist film disposing step, the resist film is exposed using the above-described underlying silver pattern in which the intersection growing is suppressed as a mask. Therefore, in the resist film developing step to be performed next, a resist pattern in which the intersection growing of the shape corresponding to the above-described underlying silver pattern is suppressed can be formed. The above-described resist pattern has an opening portion having a shape corresponding to the underlying silver pattern.

In the conductive thin wire forming step to be performed next to the resist film developing step, a plating treatment is performed at the opening portion of the resist pattern to form a metal pattern. Therefore, the metal pattern can be formed on the underlying silver pattern such that the line width of the metal pattern is not widened above the opening portion of the resist pattern. In addition, even in a case where the metal pattern is made thick, the metal pattern is formed along the shape of the resist pattern, thereby it is easy to form a conductive thin wire with a thin line width and excellent conductivity. In addition, since the above-described resist pattern has suppressed intersection growing, a conductive thin wire in which the intersection growing is suppressed can be formed.

As a result, according to the manufacturing method for a conductive substrate according to the embodiment of the present invention, a conductive substrate having a conductive thin wire with a thin line width and excellent conductivity in which the intersection growing is suppressed can be manufactured.

Hereinafter, each step included in the manufacturing method for a conductive substrate according to the embodiment of the present invention, and steps which may be included in the method, will be described.

### Underlying Silver Pattern Forming Step

The manufacturing method for a conductive substrate according to the embodiment of the present invention includes a step of forming a mesh-shaped underlying silver pattern on a side of one surface of the base material by a photographic method (underlying silver pattern forming step).

In the present invention, the “forming a mesh-shaped underlying silver pattern by a photographic method” means that the silver layer is formed by reducing the silver halide particles contained in the silver halide emulsion layer provided on the support to generate silver particles, thereby forming a mesh-shaped underlying silver pattern.

Examples of the photographic method include the following methods (a) and (b).
(a) a photographic method of subjecting a material which has a layer containing silver halide on a support to a development treatment to reduce the silver halide and to precipitate a silver layer.
(b) a photographic method (silver complex salt diffusion transfer method) of subjecting a material which has a physical development nucleus layer and a layer containing silver halide in this order on a support to a development treatment to precipitate a silver layer on the physical development nucleus, and then removing the layer containing silver halide, which is unnecessary, by water washing.

The photographic method in the underlying silver pattern forming step is not particularly limited, but is preferably carried out by the above-described method (a).

A mesh-shaped underlying silver pattern will be described with reference to the drawings.

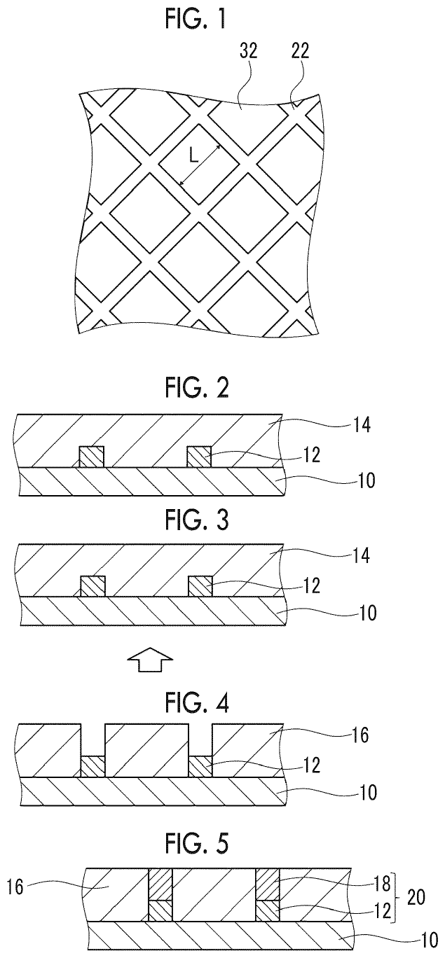

FIG. 1 is a plan view illustrating an example of a mesh-shaped underlying silver pattern.

The mesh shape is intended to be a shape including a plurality of non-thin wire portions (opening portions) 32 that are configured by intersecting underlying silver thin wires 22 and are each spaced apart from each other, as shown in FIG. 1. In FIG. 1, the non-thin wire portion 32 has a square shape having a side length of L, but the non-thin wire portion of the mesh pattern may have another shape as long as the portion is a region partitioned by the underlying silver thin wire 22, and for example, may have a polygonal shape (for example, a triangular shape, a quadrangular shape (a rhombus shape, a rectangular shape, and the like), a hexagonal shape, and a random polygonal shape). In addition, the shape of one side may be a curved shape other than a straight line or may be an arc shape. In a case where the shape of one side is an arc shape, for example, two sides facing each other may have an arc shape that is outwardly convex, and the other two sides facing each other may have an arc shape that is inwardly convex. In addition, the shape of each of the sides may be a wavy line shape in which a circular arc protruding outward and a circular arc protruding inward are continuous. Needless to say, the shape of each of the sides may be a sine curve.

The length L of one side of the non-thin wire portion 32 that is a square lattice shape is not particularly limited, and it is preferably 1,500 μm or less, more preferably 1,300 ρm or less, and still more preferably 1,000 μm or less. The lower limit value of the length L is not particularly limited but is preferably 5 μm or more, more preferably 30 μm or more, and still more preferably 80 μm or more. In a case where the length of one side of the non-thin wire portion is in the above range, it is possible to further maintain good transparency, and in a case where the conductive substrate is attached to the front surface of a display device, it is possible to visually recognize the display without an uncomfortable feeling.

From the viewpoint of visible light transmittance, an opening ratio of the underlying silver pattern is preferably 90% or more, more preferably 95% or more, and still more preferably 99% or more. The upper limit thereof is not particularly limited; however, it may be less than 100%.

The opening ratio means, in the surface of the base material on the side where the mesh-shaped underlying silver pattern is formed, a ratio (area ratio) of the area of regions where the mesh-shaped underlying silver pattern is not disposed to the total area of the surface.

The underlying silver pattern forming step is not particularly limited as long as the mesh-shaped underlying silver pattern is formed by a photographic method, but a forming step of an underlying silver pattern, which has the following Steps A to D in this order, is preferable.

Step A: a step of forming a silver halide-containing photosensitive layer (hereinafter, also referred to as a “photosensitive layer”) containing a silver halide, gelatin, and a polymer compound different from gelatin (hereinafter, also referred to as a “specific polymer”) on a base material

Step B: a step of exposing the silver halide-containing photosensitive layer and then subjecting the layer to a development treatment to form a thin wire-shaped silver-containing layer containing metallic silver, gelatin, and a specific polymer

Step C: a step of subjecting the silver-containing layer obtained in Step B to a heating treatment

Step D: a step of removing the gelatin from the silver-containing layer obtained in Step C to form an underlying silver pattern

Hereinafter, Step A to Step D will be described.

### Step A

Step A is a step of forming a photosensitive layer (silver halide-containing photosensitive layer) containing a silver halide, gelatin, and a specific polymer (a polymer compound different from gelatin) on the base material. By Step A, a base material with a photosensitive layer to be subjected to an exposure treatment which will be described later is manufactured.

First, materials (a base material, a silver halide, gelatin, and a specific polymer) which are preferably used for manufacturing the base material with a photosensitive layer will be described, and then a procedure of Step A will be described in detail.

### Base Material

The base material is not particularly limited as long as the base material can transmit the exposure light used in the resist film exposure step, and examples thereof include a plastic base material, a glass base material, and a metal base material. Among these, a plastic base material is preferable. A material of the base material may be selected according to a wavelength of exposure light used in a resist film exposure step, which will be described later. A transmittance of the base material at a wavelength of the exposure light used in the resist film exposure step is preferably 30% or more, more preferably 50% or more, and still more preferably 70% or more. The upper limit thereof is not particularly limited, and examples thereof include 100%. The above-described transmittance can be measured with a commercially available spectrophotometer.

As the base material, from the viewpoint of excellent bendability of the conductive substrate to be obtained, a base material having flexibility is preferable. Examples of the base material having flexibility include the plastic base material. The having flexibility means a base material capable of being bent, and specifically means that breakage are not caused even in a case of being bent at a bending curvature radius of 2 mm. The flexible base material has workability capable of forming a three-dimensional shape.

The thickness of the base material is not particularly limited, and is 25 to 500 μm in many cases. In a case where the conductive substrate is applied to a touch panel, the thickness of the base material may exceed 500 μm in a case where the surface of the base material is used as a touch surface.

As a material constituting the base material, a resin having a melting point of about 290° C. or lower such as polyethylene terephthalate (PET) (258° C.), polycycloolefin (134° C.), polycarbonate (250° C.), an acrylic film (128° C.), polyethylene naphthalate (269° C.), polyethylene (135° C.), polypropylene (163° C.), polystyrene (230° C.), polyvinyl chloride (180° C.), polyvinylidene chloride (212° C.), or triacetyl cellulose (290° C.) is preferable, and PET, polycycloolefin, or polycarbonate is more preferable. Among these, PET is particularly preferable from the viewpoint of excellent adhesiveness with the underlying silver pattern. The numerical value in the brackets is the melting point or the glass transition temperature.

As the material constituting the base material, polyimide may be selected in a case where the exposure light used in the resist film exposure step is transmitted therethrough.

The total light transmittance of the base material is preferably 85% to 100%. The total light transmittance is measured by using “Plastics—Determination of Total Luminous Transmittance and Reflectance” defined by Japanese Industrial Standards (JIS) K 7375:2008.

An undercoat layer may be disposed on the surface of the base material.

The undercoat layer preferably contains a specific polymer which will be described later. In a case where this undercoat layer is used, the adhesiveness of the conductive thin wire described later to the base material is further improved.

A method of forming the undercoat layer is not particularly limited, and examples thereof include a method of applying a composition for forming an undercoat layer, containing a specific polymer described later, onto a base material and carrying out a heating treatment as necessary. As necessary, the composition for forming an undercoat layer may include a solvent. The type of the solvent is not particularly limited, and examples thereof include a solvent used for a composition for forming a photosensitive layer described below. In addition, as the composition for forming an undercoat layer containing the specific polymer, latex that contains particles of the specific polymer may be used.

The thickness of the undercoat layer is not particularly limited, and it is preferably 0.02 to 0.3 μm and more preferably 0.03 to 0.2 μm from the viewpoint that the adhesiveness of the conductive layer to the base material is more excellent.

### Silver Halide

The halogen atom in the silver halide may be any one of a chlorine atom, a bromine atom, an iodine atom, or a fluorine atom and may be a combination thereof. For example, a silver halide mainly formed of silver chloride, silver bromide, or silver iodide is preferable, and a silver halide mainly formed of silver chloride or silver bromide is more preferable. Silver chlorobromide, silver iodochlorobromide, or silver iodobromide is also preferably used.

Here, for example, the “silver halide mainly composed of silver chloride” means a silver halide in which the molar fraction of ions of chlorides to the total halide ions in the silver halide composition is 50% or more. This silver halide mainly composed of silver chloride may contain a bromide ion and/or an iodide ion in addition to the chloride ion.

The silver halide is usually in a form of solid particles, and an average particle diameter of the silver halide is, in terms of sphere equivalent diameter, preferably 10 to 1000 nm, more preferably 10 to 200 nm, and still more preferably 50 to 150 nm from the viewpoint of further reducing a change in the resistance value of the conductive thin wire formed in a hot humid environment.

The sphere equivalent diameter refers to the diameter of a spherical particle having the same volume.

“The sphere equivalent diameter” used as the average particle diameter of the silver halide is an average value and is obtained by measuring the sphere equivalent diameters of 100 silver halide particles and obtaining the average thereof.

The shape of the silver halide particles is not particularly limited, and examples thereof include a spherical shape, a cubic shape, a flat plate shape (a hexagonal flat plate shape, a triangular flat plate shape, a quadrangular flat plate shape, or the like), an octahedron shape, and a tetradecahedron shape.

### Gelatin

The type of gelatin is not particularly limited, and examples thereof include lime-treated gelatin and acid-treated gelatin. In addition, a hydrolyzate of gelatin, an enzymatic decomposition product of gelatin, or gelatin modified with an amino group and/or a carboxyl group (phthalated gelatin or acetylated gelatin) may be used.

### Specific Polymer

The specific polymer is a polymer compound different from the above-described gelatin. In a case where the photosensitive layer contains the specific polymer, it is easy to improve the intensity of the underlying silver pattern formed from the photosensitive layer.

The type of specific polymer is not particularly limited as long as the specific polymer is different from gelatin, and the specific polymer is preferably a polymer that is not decomposed by a proteolytic enzyme or an oxidizing agent, which is described later, which decomposes gelatin.

Examples of the specific polymer include a hydrophobic polymer (a water-insoluble polymer), which includes, for example, at least any one resin selected from the group consisting of a (meth)acrylic resin, a styrene-based resin, a vinyl-based resin, a polyolefin-based resin, a polyester-based resin, a polyurethane-based resin, a polyamide-based resin, a polycarbonate-based resin, a polydiene-based resin, an epoxy-based resin, a silicone-based resin, a cellulose-based polymer, and a chitosan-based polymer, or a copolymer consisting of monomers that constitute these resins.

In addition, the specific polymer preferably has a reactive group that reacts with a crosslinking agent described later.

The specific polymer preferably has a particle shape. That is, the silver-containing layer formed of the photosensitive layer preferably contains particles of the specific polymer.

The specific polymer is preferably a polymer (a copolymer) represented by General Formula (1).

-(A)ₓ-(B)_{y}-(C)_{z}-(D)_{w}- General Formula (1)

In General Formula (1), A, B, C, and D respectively represent repeating units represented by General Formulae (A) to (D).

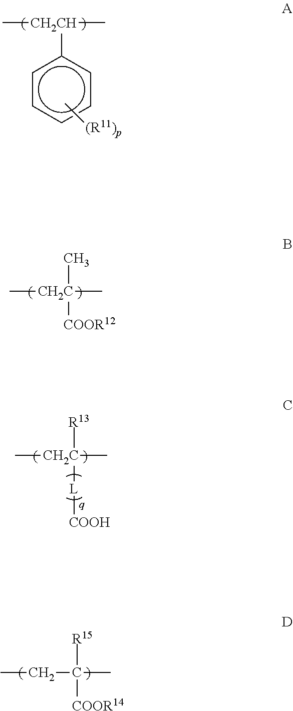

R¹¹ represents a methyl group or a halogen atom, and it is preferably a methyl group, a chlorine atom, or a bromine atom. p represents an integer of 0 to 2, and is preferably 0 or 1 and more preferably 0.

R¹² represents a methyl group or an ethyl group, and it is preferably a methyl group.

R¹³ represents a hydrogen atom or a methyl group, and it is preferably a hydrogen atom. L represents a divalent linking group, and it is preferably a group represented by General Formula (2).

—(CO—X¹)ᵣ—X²— General Formula (2)

In General Formula (2), X¹ represents an oxygen atom or NR³⁰—. Here, R³⁰ represents a hydrogen atom, an alkyl group, an aryl group, or an acyl group, each of which may have a substituent (for example, a halogen atom, a nitro group, or a hydroxyl group). R³⁰ is preferably a hydrogen atom, an alkyl group having 1 to 10 carbon atoms (for example, a methyl group, an ethyl group, an n-butyl group, or an n-octyl group), or an acyl group (for example, an acetyl group or a benzoyl group). X¹ is preferably an oxygen atom or —NH—.

X² represents an alkylene group, an arylene group, an alkylene arylene group, an arylene alkylene group, or an alkylene arylene alkylene group, and in the middle of these groups, —O—, —S—, —CO—, —COO—, —NH—, —SO₂—, —N(R³¹)—, or —N(R³¹)SO₂— may be inserted. R³¹ represents a linear or branched alkyl group having 1 to 6 carbon atoms. X² is preferably a dimethylene group, a trimethylene group, a tetramethylene group, an o-phenylene group, an m-phenylene group, a p-phenylene group, —CH₂CH₂OCOCH₂CH₂—, or —CH₂CH₂OCO(C₆H₄)—.

r represents 0 or 1.

q represents 0 or 1, and 0 is preferable.

R¹⁴ represents an alkyl group, an alkenyl group, or an alkynyl group, and it is preferably an alkyl group having 5 to 50 carbon atoms, more preferably an alkyl group having 5 to 30 carbon atoms, and still more preferably an alkyl group having 5 to 20 carbon atoms.

R¹⁵ represents a hydrogen atom, a methyl group, an ethyl group, a halogen atom, or —CH₂COOR¹⁶, and it is preferably a hydrogen atom, a methyl group, a halogen atom, or —CH₂COOR¹⁶, more preferably a hydrogen atom, a methyl group, or —CH₂COOR¹⁶, and still more preferably a hydrogen atom.

R¹⁶ represents a hydrogen atom or an alkyl group having 1 to 80 carbon atoms and may be the same as or different from R¹⁴. R¹⁶ preferably has 1 to 70 carbon atoms and more preferably 1 to 60 carbon atoms.

In General Formula (1), x, y, z, and w represent a molar ratio of each repeating unit.
x is 3% to 60% by mole, and it is preferably 3% to 50% by mole and more preferably 3% to 40% by mole.
y is 30% to 96% by mole, and it is preferably 35% to 95% by mole and more preferably 40% to 90% by mole.
z is 0.5% to 25% by mole, and it is preferably 0.5% to 20% by mole and more preferably 1% to 20% by mole.
w is 0.5% to 40% by mole, and it is preferably 0.5% to 30% by mole.

In General Formula (1), a preferred case is a case where x is 3% to 40% by mole, y is 40% to 90% by mole, z is 0.5% to 20% by mole, and w is 0.5% to 10% by mole.

The polymer represented by General Formula (1) is preferably a polymer represented by General Formula (2).

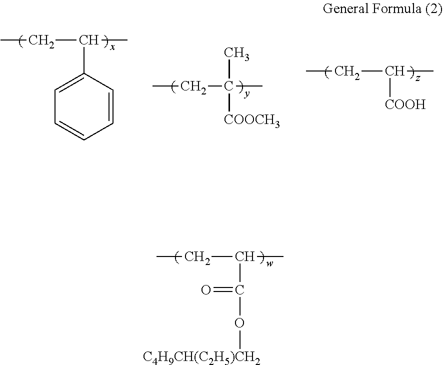

In General Formula (2), x, y, z, and w are as defined above.

The polymer represented by General Formula (1) may contain a repeating unit other than the repeating units represented by General Formulae (A) to (D) described above.

Examples of the monomers for forming other repeating units include acrylic acid esters, methacrylic acid esters, vinyl esters, olefins, crotonic acid esters, itaconic acid diesters, maleic acid diesters, fumaric acid diesters, acrylamides, unsaturated carboxylic acids, allyl compounds, vinyl ethers, vinyl ketones, vinyl heterocyclic compounds, glycidyl esters, and unsaturated nitriles. These monomers are also described in paragraphs “0010” to “0022” of JP3754745B.

From the viewpoint of hydrophobicity, acrylates or methacrylates are preferable, and hydroxyalkyl methacrylate or hydroxyalkyl acrylate is more preferable.

The polymer represented by General Formula (1) preferably contains a repeating unit represented by General Formula (E).

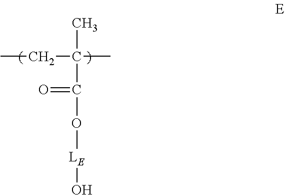

In the formula described above, LE represents an alkylene group, and it is preferably an alkylene group having 1 to 10 carbon atoms, more preferably an alkylene group having 2 to 6 carbon atoms, and still more preferably an alkylene group having 2 to 4 carbon atoms.

The polymer represented by General Formula (1) is preferably a polymer represented by General Formula (3).

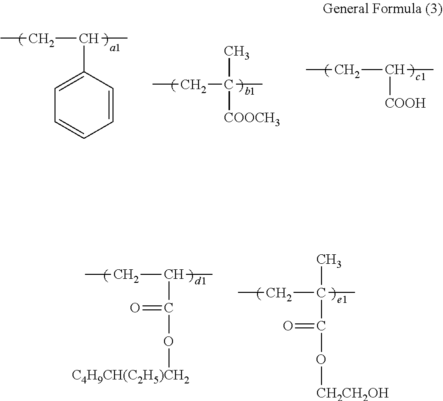

In the above formula described above, a1, b1, c1, d1, and e1 represent the molar ratio of each repeating unit, a1 represents 3 to 60 (% by mole), b1 represents 30 to 95 (% by mole), c1 represents 0.5 to 25 (% by mole), d1 represents 0.5 to 40 (% by mole), and e1 represents 1 to 10 (% by mole).

The preferred range of a1 is the same as the preferred range of the x described above, the preferred range of b1 is the same as the preferred range of the y described above, the preferred range of c1 is the same as the preferred range of the z described above, and the preferred range of d1 is the same as the preferred range of the w described above.
e1 is 1% to 10% by mole, and it is preferably 2% to 9% by mole and more preferably 2% to 8% by mole.

The specific polymer can be synthesized with reference to, for example, JP3305459B and JP3754745B.

The weight-average molecular weight of the specific polymer is not particularly limited, and it is preferably 1,000 to 1,000,000, more preferably 2,000 to 750,000, and still more preferably 3,000 to 500,000.

### Other Materials

The photosensitive layer may contain other materials other than the above-described material, as necessary.

Examples of the other materials include metal compounds belonging to Groups 8 and 9, such as a rhodium compound and an iridium compound that are used for stabilizing the silver halide and increasing the sensitivity of the silver halide. In addition, examples of the other materials include an antistatic agent, a nucleation accelerator, a spectral sensitizing dye, a surfactant, an antifoggant, a hardening agent, a black pepper inhibitor, a redox compound, a monomethine compound, and dihydroxybenzenes described in paragraphs “0220” to “0241” of JP2009-004348A.

In the photographic method, in a case where the above-described method (b) is used, examples of the other materials include a physical development nucleus. Examples of a material for the physical development nucleus include a metal sulfide obtained by mixing a colloid of gold, silver, or the like, or a water-soluble salt of palladium, zinc, or the like with a sulfide, and the like.

In addition, the photosensitive layer may include a crosslinking agent used for crosslinking the above-described specific polymers. By including the crosslinking agent, crosslinking between the specific polymers progresses, and even in a case where gelatin is decomposed and removed, linking between the metallic silver in the layer formed by the photosensitive layer.

In the photographic method, in a case where the above-described method (b) is used, a physical development nucleus layer containing a physical development nucleus may be provided between the base material and the photosensitive layer. The physical development nucleus contained in the physical development nucleus layer are as described above. For a method of forming the physical development nucleus layer, descriptions disclosed in paragraphs “0007” to “0016” of JP1993-265162A (JP-H5-265162A) can be referred to.

### Procedure of Step A

A method of forming a photosensitive layer in the step A, which contains the above-described components, is not particularly limited; however, from the viewpoint of productivity, it is preferably a method of bringing a composition for forming a photosensitive layer, containing a silver halide, gelatin, and the specific polymer, into contact with a base material and forming a photosensitive layer on the base material.

Hereinafter, a configuration of the composition for forming a photosensitive layer used in this method will be described in detail. Next, the procedure of the step will be described in detail.

### Materials Contained in Composition for Forming Photosensitive Layer

The composition for forming a photosensitive layer contains the above-described silver halide, gelatin, and specific polymer. As necessary, the specific polymer may be contained in the composition for forming a photosensitive layer in the form of a particle shape.

The composition for forming a photosensitive layer may contain a solvent, as necessary.

Examples of the solvent include water, organic solvents (for example, alcohol, ketone, amide, sulfoxide, ester, and ether), ionic liquids, and mixed solvents thereof.

A method of bringing the composition for forming a photosensitive layer into contact with a base material is not particularly limited, and examples thereof include a method of applying the composition for forming a photosensitive layer onto a base material and a method of immersing a base material in the composition for forming a photosensitive layer.

After the above-described treatment, optionally, a drying treatment may be performed.

### Silver Halide-Containing Photosensitive Layer

The photosensitive layer (silver halide-containing photosensitive layer) formed through the above-described procedure includes silver halide, gelatin, and the specific polymer.

A content of the silver halide in the photosensitive layer is not particularly limited, but from the viewpoint of functioning as a self-alignment mask pattern in a resist film exposure step described later and suppressing variation in line width of the thin wire of the underlying silver pattern formed after a development treatment described later, the content is preferably 1.0 to 10.0 g/m² and more preferably 2.0 to 7.0 g/m² in terms of silver. “In terms of silver” means that all the silver halides are converted into the mass of silver to be generated by reducing all the silver halides.

A content of the specific polymer in the photosensitive layer is not particularly limited, but from the viewpoint of more excellent formability and flexibility of the plating metal pattern on the surface of the underlying layer, the content is preferably 0.04 to 2.0 g/m² and more preferably 0.08 to 1.0 g/m².

### Step B

The step B is a step of exposing the photosensitive layer and then subjecting it to a development treatment to form a thin wire-shaped silver-containing layer containing metallic silver, gelatin, and a specific polymer.

In a case where the photosensitive layer is subjected to an exposure treatment, a latent image is formed in the exposed region.

The exposure may be performed in a patterned manner. For example, in order to obtain the mesh pattern formed of the conductive thin wire described below, a method of exposing the photosensitive layer through a mask having a mesh-shaped opening pattern or a method of scanning the photosensitive layer with laser light to expose the photosensitive layer in a mesh shape can be adopted.

The type of light that is used for exposure is not particularly limited as long as a latent image can be formed on the silver halide, and examples thereof include visible light, ultraviolet rays, and X-rays.

In a case of performing the exposure using the mask, from the viewpoint that the intersection growing is further suppressed, it is preferable to bring the mask into contact with the photosensitive layer and perform the exposure treatment.

In a case where the exposed photosensitive layer is subjected to a development treatment, metallic silver is precipitated in the exposed region (the region in which a latent image is formed).

The method of the development treatment is not particularly limited, and examples thereof include publicly known methods that are used for a silver salt photographic film, photographic printing paper, a printing plate making film, and an emulsion mask for a photomask.

In the development treatment, a developer is generally used. The type of the developer is not particularly limited, and examples thereof include a phenidone hydroquinone (PQ) developer, a metol hydroquinone (MQ) developer, and a metol ascorbic acid (MAA) developer.

The developability of the photosensitive layer is determined by the light source wavelength, the amount of light, and the sensitivity characteristics of the photosensitive layer. However, to obtain a desired line width of the underlying silver pattern, for example, the amount of light in exposure may be adjusted.

Step B may further include a fixing treatment that is carried out for the purpose of removing and stabilizing the silver halide of unexposed portions.

The fixing treatment is performed during and/or after the development. The method of the fixing treatment is not particularly limited, and examples thereof include methods that are used for a silver salt photographic film, photographic printing paper, a printing plate making film, and an emulsion mask for a photomask.

In the fixing treatment, a fixing liquid is generally used. The type of fixing liquid is not particularly limited, and examples thereof include the fixing liquid described in “Chemistry of Photographs” (written by Sasai, Photo Industry Publishing Co., Ltd.) p321.

By performing the above-described treatment, a thin wire-shaped silver-containing layer containing metallic silver, gelatin, and the specific polymer is formed, and an insulating layer containing gelatin and the specific polymer without containing metallic silver is formed.

Examples of a method of adjusting the width of the silver-containing layer include a method of adjusting the opening width of a mask used for the exposure.

In addition, in a case where a mask is used at the time of exposure, the width of the silver-containing layer to be formed can be adjusted by adjusting the exposure amount. For example, in a case where the opening width of the mask is narrower than the target width of the silver-containing layer, the width of the region in which a latent image is formed can be adjusted by increasing the exposure amount more than usual. That is, the line width of the silver-containing layer and the conductive thin wire to be formed can be adjusted by the exposure amount.

Furthermore, in a case where laser light is used, the exposed region can be adjusted by adjusting the focusing range and/or the scanning range of the laser light.

The width of the silver-containing layer is preferably 0.5 μm or more and less than 5.0 μm and, from the viewpoint of the inconspicuousness of the conductive thin wire to be formed, more preferably 3.0 μm or less and still more preferably 1.4 μm or less.

The silver-containing layer obtained through the above-described procedure has a thin wire shape, and the width of the silver-containing layer refers to the length (width) of the silver-containing layer in a direction perpendicular to a direction in which the thin wire-shaped silver-containing layer extends.

### Step C

Step C is a step of performing a heating treatment on the silver-containing layer and the insulating layer (hereinafter, both are also referred to as “silver-containing layer or the like”) obtained in Step B. In a case where this step is carried out, fusion welding between specific polymers in the silver-containing layer or the like progresses, and thus the strength of the silver-containing layer or the like is improved.

The method of the heating treatment is not particularly limited, and examples thereof include a method of bringing the silver-containing layer or the like into contact with superheated vapor and a method of heating with a temperature control device (for example, a heater), and a method of bringing the silver-containing layer or the like into contact with superheated vapor is preferable.

The superheated vapor may be superheated steam or may be a mixture obtained by mixing superheated steam with another gas.

The time of contact between the superheated vapor and the silver-containing layer or the like is not particularly limited, and it is preferably 10 to 70 seconds.

The supply amount of the superheated vapor is preferably 500 to 600 g/m³, and the temperature of the superheated vapor is preferably 100° C. to 160° C. (preferably 100° C. to 120° C.) at 1 atm.

Preferable heating conditions in the method of heating the silver-containing layer or the like in a temperature control device are 100° C. to 200° C. (preferably 100° C. to 150° C.) and 1 to 240 minutes (preferably 60 to 150 minutes).

### Step D

Step D is a step of removing gelatin in the silver-containing layer obtained in Step C. By performing this step, the gelatin is removed from the silver-containing layer or the like, and a space is formed in the silver-containing layer or the like.

The method of removing gelatin is not particularly limited, and examples thereof include a method of using a proteolytic enzyme (hereinafter, also referred to as a “method 1”) and a method of decomposing and removing gelatin using an oxidizing agent (hereinafter, also referred to as a “method 2”).

Examples of the proteolytic enzyme that is used in the method 1 include enzymes publicly known as vegetable or animal enzymes that are capable of hydrolyzing proteins such as gelatin. Examples of the proteolytic enzyme include pepsin, rennin, trypsin, chymotrypsin, cathepsin, papain, ficin, thrombin, renin, collagenase, bromelain, and a bacterial protease, and trypsin, papain, ficin, or a bacterial protease is preferable.

The procedure of the method 1 only needs to be a method of bringing the silver-containing layer or the like and the above-described proteolytic enzyme into contact with each other, and examples thereof include a method of bringing the silver-containing layer or the like and a treatment liquid (hereinafter, also referred to as “enzyme solution”) including the proteolytic enzyme into contact with each other. Examples of the contact method include a method of immersing the silver-containing layer or the like in the enzyme solution and a method of applying the enzyme solution onto the silver-containing layer or the like.

The content of the proteolytic enzyme in the enzyme solution is not particularly limited, and from the viewpoint that degree of decomposition and removal of the gelatin is easily controlled, the content is preferably 0.05% to 20% by mass and more preferably 0.5% to 10% by mass with respect to the total amount of the enzyme solution.

The enzyme solution includes water in addition to the above-described proteolytic enzyme in many cases.

As necessary, the enzyme solution may contain other additives (for example, a pH buffering agent, an antibacterial compound, a wetting agent, and a preservative).

The pH of the enzyme solution is selected so that the action of the enzyme can be obtained to the maximum; however, in general, it is preferably 5 to 9.

The temperature of the enzyme solution is preferably a temperature at which the action of the enzyme is enhanced. Specifically, the temperature thereof is preferably in a range of 25° C. to 45° C.

As necessary, a washing treatment in which the obtained silver-containing layer or the like is washed with warm water after the treatment with the enzyme solution may be carried out.

The washing method is not particularly limited, and a method of bringing the silver-containing layer or the like into contact with warm water is preferable. Examples thereof include a method of immersing the silver-containing layer or the like in warm water and a method of applying warm water onto the silver-containing layer or the like.

As the temperature of the warm water, an appropriately optimum temperature for the type of the proteolytic enzyme to be used is selected, and from the viewpoint of productivity, is preferably 20° C. to 80° C. and more preferably 40° C. to 60° C.

The contact time (cleaning time) of the warm water and the silver-containing layer or the like is not particularly limited and, from the viewpoint of productivity, is preferably 1 to 600 seconds and more preferably 30 to 360 seconds.

The oxidizing agent that is used in the method 2 may be any oxidizing agent capable of decomposing gelatin, and an oxidizing agent having a standard electrode potential of +1.5 V or higher is preferable. The standard electrode potential is intended to be a standard electrode potential (25° C., E⁰) of the oxidizing agent with respect to the standard hydrogen electrode in the aqueous solution.

Examples of the oxidant include persulfuric acid, percarbonic acid, perphosphoric acid, peroxoperchloric acid, peracetic acid, meta-chloroperbenzoic acid, aqueous hydrogen peroxide, hypochlorous acid, periodic acid, potassium permanganate, ammonium persulfate, ozone, hypochlorous acid, and salts thereof, but from the viewpoints of productivity and economy, hydrogen peroxide water (standard electrode potential: 1.76 V), hypochlorous acid or a salt thereof is preferable, and sodium hypochlorite is more preferable.

The procedure of the method 2 only needs to be a method of bringing the silver-containing layer or the like and the above-described oxidant into contact with each other, and examples thereof include a method of bringing the silver-containing layer or the like and a treatment liquid (hereinafter, also referred to as “oxidant liquid”) including the oxidant into contact with each other. Examples of the contact method include a method of immersing the silver-containing layer or the like in the oxidizing agent solution and a method of applying the oxidizing agent solution onto the silver-containing layer or the like.

The type of solvent contained in the oxidizing agent solution is not particularly limited, and examples thereof include water and an organic solvent.

### Step E

The underlying silver pattern forming step may further include Step E of performing a smoothing treatment after Step D. By performing Step E, a conductive thin wire having more excellent handling resistance (film strength) is obtained.

A method for the smoothing treatment is not particularly limited, and it is, for example, preferably a calender treatment step of causing a base material having a silver-containing layer or the like to pass between at least a pair of rolls under pressurization. Hereinafter, the smoothing treatment using a calender roll will be referred to as a calender treatment.

Examples of the roll that is used for the calender treatment include a plastic roll and a metal roll, where a plastic roll is preferable from the viewpoint of preventing wrinkles.

The pressure between the rolls is not particularly limited and is preferably 2 MPa or more, more preferably 4 MPa or more and is preferably 120 MPa or less. The pressure between rolls can be measured using PRESCALE (for high pressure) manufactured by FUJIFILM Corporation.

The smoothing treatment temperature is not particularly limited; however, it is preferably 10° C. to 100° C. and more preferably 10° C. to 50° C.

### Step Z

The underlying silver pattern forming step may have Step Z of forming a silver halide-free layer containing gelatin and the specific polymer on the base material before Step A. In a case where Step Z is carried out, a silver halide-free layer is formed between the base material and the silver halide-containing photosensitive layer. This silver halide-free layer serves as a so-called antihalation layer and contributes to improving the adhesiveness between the conductive thin wire and the base material.

The silver halide-free layer contains the above-described gelatin and specific polymer. On the other hand, the silver halide-free layer does not contain a silver halide.

The ratio of the mass of the specific polymer to the mass of the gelatin (the mass of the specific polymer/the mass of the gelatin) in the silver halide-free layer is not particularly limited, and it is preferably 0.1 to 5.0 and more preferably 1.0 to 3.0.

The content of the specific polymer in the silver halide-free layer is not particularly limited. It is 0.03 g/m² or more in a large number of cases, and it is preferably 1.0 g/m² or more from the viewpoint that the adhesiveness of the conductive thin wire portion is more excellent. The upper limit thereof is not particularly limited and is 1.63 g/m² or less in a large number of cases.

A method of forming the silver halide-free layer is not particularly limited, and examples thereof include a method of applying a composition for forming a layer, containing gelatin and the specific polymer, onto a base material and carrying out a heating treatment as necessary.

For example, the composition for forming a layer may contain a solvent as necessary. Examples of the type of solvent include the solvent that is used in the above-described composition for forming a photosensitive layer.

The thickness of the silver halide-free layer is not particularly limited. It is 0.05 μm or more in a large number of cases, and it is preferably more than 1.0 μm and more preferably 1.5 μm or more from the viewpoint that the adhesiveness of the conductive thin wire portion is more excellent. The upper limit is not particularly limited, but is preferably less than 3.0 μm.

A line width of the underlying silver pattern to be formed by the above-described step is preferably 0.5 μm or more and less than 5.0 μm and, from the viewpoint of the inconspicuousness of the conductive thin wire to be formed, more preferably 3.0 μm or less and still more preferably 1.4 μm or less.

The line width of the underlying silver pattern is obtained by observing the film surface of the conductive substrate in a vertical direction using a scanning electron microscope (SEM). A more detailed measurement method is the same as the method in Examples described later.

In addition, from the viewpoint that the variation in line width of the conductive thin wire to be formed can be reduced, the thickness of the underlying silver pattern is preferably 1.7 μm or less, more preferably 1.5 μm or less, still more preferably 1.0 μm or less, and particularly preferably 0.8 μm or less. The lower limit thereof is not particularly limited, but is preferably 0.2 μm or more.

The thickness of the underlying silver pattern is obtained by the following method.

Any 10 locations of the base material on which the underlying silver pattern has been formed are selected, and a cross section cut in a direction orthogonal to the extending direction of the underlying silver thin wire at each location is observed using an SEM. A maximum value of the underlying silver thin wire in the thickness direction is measured from the obtained observation image. The thickness of the underlying silver pattern is obtained by calculating an arithmetic average value of maximum values in the thickness direction measured at the selected 10 locations. A more detailed measurement method will be described in Examples later.

In a case where the region of the underlying silver pattern can be discriminated in the conductive substrate obtained through the step described later, the above-described measurement may be performed on the conductive substrate to measure the thickness of the underlying silver pattern.

### Resist Film Disposing Step

The manufacturing method for a conductive substrate according to the embodiment of the present invention includes a step (resist film disposing step) of disposing a resist film on the side of the surface of the base material on which the underlying silver pattern is formed. More specifically, as shown in FIG. 2, by performing this step, the underlying silver pattern 12 and the resist film 14 are disposed on the base material 10. The resist film 14 is disposed to cover the underlying silver pattern 12.

The deposition of the resist film can be performed by a known method, and examples thereof include a method of applying a resist composition containing a component of the resist film on the side of the surface of the base material on which the underlying silver pattern is formed, and a method of bonding the surface of the base material on which the underlying silver pattern is formed and a film-shaped resist film.

The resist film to be disposed in the resist film disposing step is preferably a negative tone resist in which an exposed portion is insoluble in a developer used in the resist film developing step. As the negative tone resist, a known negative tone resist can be used. Among these, a negative tone resist in which solubility in an alkali developer is reduced by exposure is preferable.

### Resist Film Exposure Step

The manufacturing method for a conductive substrate according to the embodiment of the present invention includes a step (resist film exposure step) of irradiating the resist film with light from a side of a surface of the base material on which the underlying silver pattern is not formed.

In the resist film exposure step, the entire surface of the base material is irradiated with light from the side of the surface on which the underlying silver pattern is not formed, and the resist film is exposed using the underlying silver pattern as a mask. More specifically, as shown in FIG. 3, in a case where the light is irradiated from the direction indicated by the white arrow, the underlying silver pattern 12 functions as a mask, and the resist film located on the underlying silver pattern is not exposed.

A wavelength of the exposure light used in the resist film exposure step is not particularly limited as long as the resist film can be exposed and the above-described base material can be transmitted. Examples of an exposure light and an exposure light source used in the resist film exposure step include g-rays (wavelength: 436 nm), i-rays (365 nm), a KrF excimer laser (248 nm), an ArF excimer laser (193 nm), an F₂ excimer laser (157 nm), and the like. In a case where a laser is used as the exposure light source, in the above-described exposure, the exposure may be performed by scanning the laser such that the entire surface of the base material is irradiated with the laser.

An exposure amount in the resist film exposure step can be appropriately adjusted, but is preferably 50 to 2,000 mJ/cm², more preferably 100 to 1,000 mJ/cm², and still more preferably 200 to 500 mJ/cm².

In addition, in the resist film exposure step, the resist film may be heated (pre-baked) before the exposure, or the resist film may be heated (post-baked) after the exposure. The above-described heating can be appropriately adjusted depending on the resist film to be used, and examples of the condition of the above-described heating include a condition of heating at 60° C. to 150° C. for 10 to 300 seconds.

### Resist Film Developing Step

The manufacturing method for a conductive substrate according to the embodiment of the present invention includes a step of developing the exposed resist film to form a resist pattern (resist film developing step).

In the resist film developing step, the exposed resist film is developed, and the resist film of a portion disposed on the underlying silver pattern is removed, thereby a resist pattern having an opening portion having a shape corresponding to the underlying silver pattern is formed. That is, the resist pattern has a shape that covers only a portion where the underlying silver pattern is not formed. Since the resist pattern is irradiated with the light from the side of the surface of the base material on which the underlying silver pattern is not formed, to expose using the underlying silver pattern as a mask as described above, a resist pattern self-aligned with the underlying silver pattern is formed. More specifically, by performing this step, as shown in FIG. 4, the underlying silver pattern 12 and the resist pattern 16 are disposed on the base material 10. As shown in FIG. 4, the resist pattern 16 has an opening portion corresponding to the position of the underlying silver pattern 12.

In the resist film developing step, the resist film can be developed using a known developer, and the developer may be selected according to the type of the resist film. Examples of the developer include an alkali developer and an organic solvent developer.

In addition, in the resist film developing step, rinsing with a rinsing liquid may be performed after the development. As the rinsing liquid, the developer used may be used as the rinsing liquid, or another rinsing liquid may be used. Examples of the above-described other rinsing liquids include water (preferably, ion-exchanged water or ultrapure water).

The resist pattern formed in the resist film developing step preferably has a trapezoidal shape (reverse taper shape) in which the side of the underlying silver pattern is a short side, or a rectangular shape.

### Conductive Thin Wire Forming Step

The manufacturing method for a conductive substrate according to the embodiment of the present invention includes a step (conductive thin wire forming step) of performing a plating treatment using the underlying silver pattern as a seed layer to form a metal pattern on the underlying silver pattern, thereby obtaining a conductive thin wire.

In the conductive thin wire forming step, the resist pattern obtained in the resist film developing step is used as a plating resist, and a plating treatment is performed using the underlying silver pattern as a seed layer to form a selectively plating film on the underlying silver pattern, thereby obtaining a metal pattern. More specifically, as shown in FIG. 5, by performing this step, the metal pattern 18 is formed on the underlying silver pattern 12, and the conductive thin wire 20 is obtained. As shown in FIG. 5, the conductive thin wire 20 is constituted of the underlying silver pattern 12 and the metal pattern 20 (plating film).

A method of the plating treatment is not particularly limited, and may be electroless plating (chemical reduction plating, substitution plating, and the like) or electrolytic plating, but electroless plating is preferable. As the electroless plating, a well-known electroless plating technique is used.

Examples of the plating treatment include a silver plating treatment, a copper plating treatment, a nickel plating treatment, and a cobalt plating treatment, and from the viewpoint that the conductivity of the conductive thin wire is more excellent, a silver plating treatment or a copper plating treatment is preferable, and a silver plating treatment is more preferable.

Components in the plating liquid used in the plating treatment are not particularly limited. Typically, in addition to the solvent (for example, water), the plating liquid mainly includes 1.metal ions for plating, 2. a reducing agent, 3. an additive (stabilizer) for improving the stability of the metal ions, and 4. a pH adjuster. In addition to these, the plating liquid may contain a known additive such as a stabilizer of the plating liquid.

The type of the metal ions for plating in the plating liquid is appropriately selected depending on the metal species to be deposited, and examples thereof include silver ions, copper ions, nickel ions, and cobalt ions.

A commercially available plating liquid may be used as the plating liquid.

The above-described plating treatment procedure is not particularly limited as long as it is a method of bringing the underlying silver pattern into contact with the plating liquid, and examples thereof include a method of immersing the underlying silver pattern in the plating liquid and a method of applying the plating liquid to the underlying silver pattern.

A contact time between the underlying silver pattern and the plating solution is not particularly limited, and from the viewpoint that the conductivity of the conductive thin wire is more excellent and the viewpoint of productivity, the contact time is preferably 20 seconds to 30 minutes.

After the conductive thin wire forming step is performed, the resist pattern may be removed. Examples of a method of removing the resist pattern include a method of peeling off the resist pattern using a peeling liquid having high affinity with a material constituting the resist pattern. As the peeling liquid, a known peeling liquid can be used.

The resist pattern may be removed, and a portion of the resist pattern which is made insoluble in a developer by exposure may be used as a constituent element of a product or the like. The resist pattern used without being removed in this manner is also referred to as a permanent resist. In a case where the resist pattern is used as a permanent resist, it is preferable that the haze and the retardation of the permanent resist are less likely to change with the passage of time. Examples of a resist film which can form such a permanent resist include an ATN1021 negative-type acrylic resist manufactured by Dow Chemical, and the like.

In addition, after the conductive thin wire forming step is performed, a blackening layer may be formed on a surface opposite to the base material on which the conductive thin wire is formed.

The blackening layer prevents reflection of light in the conductive thin wire, and improves visibility of the light ray passing through the conductive substrate. The blackening layer can be formed by a plating treatment such as black chromium plating, black nickel plating, and black alumite plating.

In addition, after the conductive thin wire forming step is performed, a step of performing a heating treatment may be included. In a case where this step is performed, a conductive thin wire having more excellent conductivity can be obtained. A method of performing a heating treatment on the conductive thin wire is not particularly limited, and examples thereof include the methods described in Step C.

From the viewpoint that a conductive thin wire having excellent conductivity is easily formed, a thickness of the metal pattern to be formed (thickness of the plating film) is preferably 0.5 μm or more, more preferably 1.0 μm or more, and still more preferably 1.5 μm or more. In a case where the thickness of the above-described metal pattern is within the preferred range, it is considered that a conductive thin wire having less influence of the variation in thickness of the metal pattern and excellent conductivity is easily formed. The upper limit thereof is not particularly limited, but is preferably 10 μm or less, more preferably 8.0 μm or less, and still more preferably 6.0 μm or less.

The thickness of the above-described metal pattern can be measured by the same method as the method for measuring the thickness of the above-described underlying silver pattern in the conductive substrate. A more detailed measurement method will be described in Examples later.

The thickness of the above-described metal pattern can be adjusted by the line width of the underlying silver pattern, the thickness of the resist film, the plating treatment time in the conductive thin wire forming step, and the like.

In the conductive substrate, a line width of the conductive thin wire is preferably 0.5 μm or more and less than 5.0 μm, from the viewpoint that the conductive thin wire is less visible, more preferably 3.0 μm or less, still more preferably 1.4 μm or less, and particularly preferably 1.0 μm or less.

The line width of the above-described conductive thin wire can be measured by performing the same method as the method for measuring the thickness of the above-described underlying silver pattern in the conductive substrate. A more detailed measurement method will be described in Examples later.

The line width of the conductive thin wire can be adjusted by the line width of the underlying silver pattern.

In addition, in the conductive substrate, from the viewpoint of forming the conductive thin wire with a thin line width and excellent conductivity, it is also preferable that the ratio of the thickness of the metal pattern (thickness of the plating film) to the line width of the conductive thin wire is 0.4 or more. The above-described ratio is more preferably 0.8 or more and still more preferably 1.0 or more. The upper limit of the above-described ratio is not particularly limited, but is preferably 5.0 or less and more preferably 4.0 or less.

The height of the above-described conductive thin wire can be measured by performing the same method as the method for measuring the thickness of the above-described underlying silver pattern in the conductive substrate. A more detailed measurement method will be described in Examples later.

In addition, in the conductive substrate, from the viewpoint of forming the conductive thin wire with a thin line width and excellent conductivity, it is also preferable that the ratio of the height of the conductive thin wire to the line width of the conductive thin wire is 0.80 or more. The above-described ratio is more preferably 1.10 or more, still more preferably 1.20 or more, and particularly preferably 2.00 or more. The upper limit of the above-described ratio is not particularly limited, but is preferably 5.00 or less and more preferably 4.00 or less.

The height of the above-described conductive thin wire can be measured by performing the same method as the method for measuring the thickness of the above-described underlying silver pattern in the conductive substrate. A more detailed measurement method will be described in Examples later. The height of the conductive thin wire is a total value of the thickness of the underlying silver pattern and the thickness of the metal pattern (plating film).

The above-described ratio can be adjusted by the line width of the underlying silver pattern, the thickness of the resist film, the plating treatment time in the conductive thin wire forming step, and the like.

In addition, in the conductive substrate, the intersection growing ratio of the conductive thin wire is preferably 1.0 to 1.6 and more preferably 1.0 to 1.5.

In the present specification, the intersection growing is defined as follows.

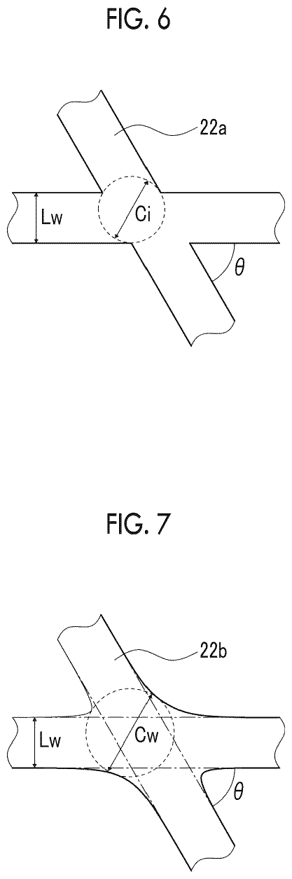

FIGS. 6 and 7 are enlarged plan views of the intersection part of the conductive thin wire for describing the intersection growing.

FIG. 6 shows an intersection part of the conductive thin wire in a case in which there is no intersection growing. In FIG. 6, the conductive thin wires 22a have a line width of Lw, and intersect with each other at an angle θ formed by the two conductive thin wires 22a to form an intersection part. That is, in FIG. 6, the conductive thin wire 22a extends from the intersection part in four directions. Provided that θ is more than 0° and 90° or less. In the case shown in FIG. 6, the diameter Ci of the maximum inscribed circle having the maximum diameter in the region forming the intersection part is, using the angle 0 and the line width Lw of the conductive thin wire, given by Ci=2*Lw/(1+sinθ/2) in a case where the angle θ is 0° or more and less than 60°, and is given by Ci=Lw/((sinθ)*(cosθ/2)) in a case where the angle θ is 60° to 90°.

FIG. 7 shows an intersection part of a conductive thin wire in a case where there is an intersection growing. In FIG. 7, the conductive thin wires 22b intersect at an angle θ formed by the two conductive fine lines 22b to form an intersection part. That is, in FIG. 7, the conductive thin wire 22b extends from the intersection part in four directions. The one-dot chain line in FIG. 7 is an imaginary line in a case where there is no intersection growing at the intersection part formed by the conductive thin wires 22b. In addition, a line width of the conductive thin wire 22b in the region where the intersection growing is not generated is Lw. In FIG. 7, a diameter Cw of a maximum inscribed circle having a maximum diameter in a region forming the intersection part is obtained.

Here, the intersection growing rate is given by the following expression.

$$( intersection growing ratio ) = Cw / Ci$$

That is, the intersection growing ratio corresponds to a ratio of the diameter Cw of the maximum inscribed circle of the intersection part in which the intersection growing is generated to the diameter Ci of the maximum inscribed circle of the intersection part in a case where there is no intersection growing. The diameter Ci of the maximum inscribed circle is obtained from the line width Lw of the conductive thin wire measured by the above-described method and the angle θ formed at the intersection part of the two conductive thin wires. For example, in a case where the diameter Ci of the maximum inscribed circle is a formed angle θ of 90°, that is, the conductive thin wire is orthogonal, the diameter Ci of the maximum inscribed circle is √2 times the line width Lw of the conductive thin wire.

The intersection growing is obtained by observing the conductive substrate with an SEM from the plane of the conductive substrate in the vertical direction and analyzing the obtained image. A more detailed measurement method will be described in Examples later.

In FIGS. 6 and 7, the aspect in which the conductive thin wire extends from the intersection part in four directions has been described, but as described above, other aspects may be adopted. Even in a case of the aspect other than FIGS. 6 and 7, the diameter Ci of the maximum inscribed circle and the diameter Cw of the maximum inscribed circle are obtained by observing with the SEM as described above, and analyzing the obtained image.

The above-described intersection growing ratio corresponds to a numerical value of how many times the effective line width of the intersection is increased by the intersection growing as compared with a case where there is no intersection growing. In a case where there is no intersection growing, the intersection growing ratio is 1. In a case where there is an intersection growing, the intersection growing ratio is more than 1, in a case where the intersection point is thinned, the intersection growing ratio is less than 1.

The diameter Cw of the maximum inscribed circle is obtained by adopting an average value of maximum diameters of circles inscribed in the five intersection parts, and the Lw is obtained by adopting an average value of line widths of midpoint parts between the intersection parts in a case where the line widths are measured at five points.

### Applications of Conductive Substrate

The conductive substrate obtained by the manufacturing method for a conductive substrate according to the embodiment of the present invention can be applied to various applications, such as a touch panel (or a touch panel sensor), a semiconductor chip, various electric wiring boards, flexible printed circuits (FPC), chip on film (COF), tape automated bonding (TAB), an antenna, a multilayer interconnection board, and a motherboard. Among these, the conductive substrate is preferably used for a touch panel (capacitance-type touch panel).

In the touch panel including the conductive substrate, the conductive thin wire described above can effectively function as a detection electrode. In a case where the conductive substrate is used for a touch panel, examples of a display panel used in combination with the conductive substrate include a liquid crystal panel and an organic light emitting diode (OLED) panel, and a combination with an OLED panel is preferable.

Examples of the use application of the conductive substrate other than those described above include an electromagnetic wave shield that blocks electromagnetic waves such as radio waves and microwaves (ultra-high frequency radio waves), generated from electronic apparatuses such as a personal computer and a workstation and prevents static electricity. This electromagnetic wave shield can be used not only for the main body of the personal computer but also for an electronic apparatus such as an imaging apparatus or an electronic medical apparatus.

The conductive substrate can also be used for a transparent exothermic body.

The conductive substrate may be used in a form of a laminate including the conductive substrate and other members such as a pressure-sensitive adhesive sheet and a peeling sheet in a case of handling and transportation. The peeling sheet functions as a protective sheet for preventing the occurrence of scratching on the conductive substrate during the transportation of the laminate.

In addition, the conductive substrate may be handled in the form of a composite body having, for example, a conductive substrate, a pressure-sensitive adhesive sheet, and a protective layer in this order.

Basically, the present invention is configured as described above. The present invention is not limited to the above-described embodiment, and various improvements and modifications can be made within a range not departing from the scope of the present invention.

### EXAMPLES

Hereinafter, the present invention will be described in more detail with reference to Examples.

The materials, the amounts of materials used, the proportions, the treatment details, the treatment procedure, and the like shown in Examples below may be modified as appropriate as long as the modifications do not depart from the spirit of the present invention. Therefore, the scope of the present invention should not be construed as being limited to Examples shown below.

In Examples 1 to 10 and Comparative Example 1, a conductive substrate was manufactured, and the evaluation items of the intersection growing rate, the line width, the variation in line width, the conductivity, and the visibility were evaluated. Hereinafter, Examples 1 to 10 and Comparative Example 1 will be described.

### EXAMPLE 1

### Preparation of Silver Halide Emulsion

The following solution 2 and the following solution 3 were simultaneously added for 20 minutes to the following solution 1 held at a temperature of 38° C. and a pH (hydrogen ion exponent) 4.5 in amounts corresponding to 90% of the entire amounts while stirring the solutions. As a result, nuclear particles having a size of 0.07 μm were formed. Next, the following solution 4 and the following solution 5 were added to the mixed solution for 8 minutes, and the remaining 10% amounts of the solution 2 and the solution 3 were further added for 2 minutes. As a result, the particles grew to a size of 0.09 μm. Furthermore, 0.15 g of potassium iodide was added to the mixed solution and aged for 5 minutes so that particle formation finished.

### Solution 1

| | | |
|---|---|---|
| Water | 750 | ml |
| Gelatin | 8.6 | g |
| Sodium chloride | 3 | g |
| 1,3-Dimethylimidazolidine-2-thione | 20 | mg |
| Sodium benzenethiosulfonate | 10 | mg |
| Citric acid | 0.7 | g |
| Solution 2: | | |
| Water | 300 | mL |
| Silver nitrate | 150 | g |
| Solution 3: | | |
| Water | 300 | ml |
| Sodium chloride | 38 | g |
| Potassium bromide | 32 | g |
| Potassium hexachloroiridate (III) | 5 | mL |
| (0.005% KCl 20% aqueous solution) | | |
| Ammonium hexachlororhodate | 7 | mL |
| (0.001% NaCl 20% aqueous solution) | | |
| Solution 4: | | |
| Water | 100 | mL |
| Silver nitrate | 50 | g |
| Solution 5: | | |
| Water | 100 | mL |
| Sodium chloride | 13 | g |
| Potassium bromide | 11 | g |
| Yellow prussiate of potash | 5 | mg |

Next, the particles were washed with water by flocculation using an ordinary method. Specifically, the temperature of the mixed solution described above was decreased to 35° C. and the pH of the mixed solution was decreased (the pH thereof was in a range of 3.6±0.2) using sulfuric acid until the particles of silver halide was precipitated. Next, about 3 L of the supernatant solution was removed from the mixed solution (the first water washing). Furthermore, 3 L of distilled water was added to the mixed solution from which the supernatant solution had been removed, and then sulfuric acid was added thereto until the silver halide was precipitated. 3 L of the supernatant solution was again removed from the mixed solution (the second water washing). The same operation as the second water washing was repeated once more (the third water washing), whereby the water washing and desalting steps were completed.

After the water washing and desalting, the emulsion was adjusted to pH 6.4 and pAg 7.5, 2.5 g of gelatin, then 10 mg of sodium benzenethiolsulfonate, 3 mg of sodium benzenethiosulfinate, 15 mg of sodium thiosulfate, and 10 mg of chloroauric acid were added to the emulsion, and chemosensitization was performed at 55° C. to obtain the optimum sensitivity. Next, 100 mg of 1,3,3a, 7-tetraazaindene as a stabilizer and 100 mg of PROXEL (trade name, manufactured by ICI Co., Ltd.) as a preservative were further added to the emulsion.

The finally obtained emulsion was a silver iodochlorobromide cubic particle emulsion having an average particle diameter of 0.10 μm and a coefficient of variation of 9%, in which the content of silver iodide was 0.08 mol %, and the ratio of silver chlorobromide was 70 mol % of silver chloride and 30 mol % of silver bromide.

### Preparation of Composition for Forming Photosensitive Layer

1,3,3a, 7-tetraazaindene (1.2×10⁻⁴mol/mol Ag), hydroquinone (1.2×10⁻² mol/mol Ag), citric acid (3.0×10⁻⁴ mol/mol Ag), 2,4-dichloro-6-hydroxy-1,3,5-triazine sodium salt (0.90 g/mol Ag), and a small amount of a hardening agent were added to the emulsion to obtain a composition. The pH of the composition was then adjusted to 5.6 using citric acid.

A polymer latex containing a polymer represented by (P-1) shown below (hereinafter, also referred to as a “polymer 1”), a dispersing agent consisting of a dialkylphenyl PEO (PEO is an abbreviation for polyethylene oxide) sulfuric acid ester, and water (in the polymer latex, the ratio of the mass of the dispersing agent to the mass of the polymer 1 (the mass of the dispersing agent/the mass of the polymer 1, unit: g/g) is 0.02, and the solid content is 22% by mass) was added to the above composition so that the ratio of the mass of the polymer 1 to the total mass of the gelatin in the composition (the mass of the polymer 1/the mass of the gelatin, unit: g/g) was 0.25/1, whereby a polymer latex-containing composition was obtained. Here, in the polymer latex-containing composition, the ratio of the mass of the gelatin to the mass of the silver derived from the silver halide (the mass of the gelatin/the mass of the silver derived from the silver halide, unit: g/g) was 0.11.

Furthermore, EPOXY RESIN DY022 (trade name, manufactured by Nagase ChemteX Corporation) as a crosslinking agent was added. The addition amount of the crosslinking agent was adjusted such that the amount of the crosslinking agent in the silver halide-containing photosensitive layer described below was 0.09 g/m².

In such a manner as described above, a composition for forming a photosensitive layer was prepared.

The polymer 1 was synthesized, for example, with respect to JP3305459B and JP3754745B.

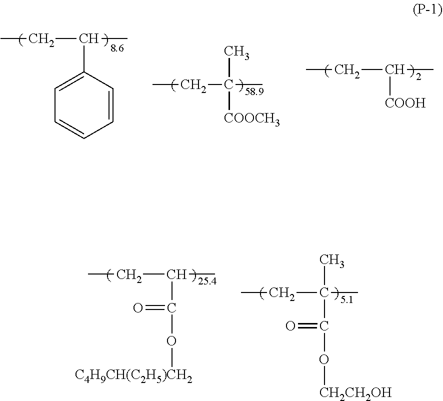

### Formation of Undercoat Layer

The above-described polymer latex was applied onto a polyethylene terephthalate film having a thickness of 40 μm (“a long roll-shaped film manufactured by FUJIFILM Corporation”) to provide an undercoat layer having a thickness of 0.05 μm. This treatment was carried out in a roll-to-roll manner, and each of the following treatments (steps) was also carried out in the same manner as the roll-to-roll manner. Here, the roll width was 1 m, and the roll length was 1,000 m.

### Step Z1, Step A1

Next, a composition for forming a silver halide non-containing layer obtained by mixing the polymer latex and gelatin, and the above-described composition for forming a photosensitive layer were simultaneously applied to the undercoat layer to form a silver halide non-containing layer, and a silver halide-containing photosensitive layer on the undercoat layer.

The thickness of the silver halide non-containing layer was 2.0 μm, the mixing mass ratio (polymer 1/gelatin) of the polymer 1 to the gelatin in the silver halide non-containing layer was 2/1, and the content of the polymer 1 was 1.3 g/m².

In addition, the thickness of the silver halide-containing photosensitive layer was 2.0 μm, the mixing mass ratio of the polymer 1 to the gelatin in the silver halide-containing photosensitive layer (the polymer 1/the gelatin) was 0.25/1, and the content of the polymer 1 was 0.15 g/m².

### Step B1

The produced photosensitive layer described above was irradiated with parallel light with a high-pressure mercury lamp as a light source through a lattice-shaped photomask to expose the above-described photosensitive layer. As a photo mask, a mask for pattern formation was used. The photosensitive layer was exposed in a state where the photo mask was in contact with the photosensitive layer. The shape and exposure conditions of the photo mask were set such that a unit square lattice having an opening portion with a side length L of 400 μm was formed in the conductive substrate to be formed in Step E1, and the line width Lw of the conductive thin wire was set to 2.1 μm.

The developer described later was applied to the exposed photosensitive layer, and further the photosensitive layer was treated with a fixing liquid (trade name: N3X-R for CN16X, manufactured by FUJIFILM Corporation), thereby performing a development treatment. Thereafter, the photosensitive layer was rinsed with pure water at 25° C. and dried to obtain the sample A having a silver-containing thin wire containing metallic silver, which was formed in a mesh pattern. In the sample A, a mesh pattern region (corresponding to the underlying silver pattern) having a size of 10 cm×10 cm was formed.

The line width of the silver-containing thin wire was measured using a microscope “VHX-5000” manufactured by KEYENCE CORPORATION.

### Composition of Developer

The following compounds are contained in 1 liter (L) of the developer.

| | |
|---|---|
| Hydroquinone | 0.037 mol/L |
| N-methylaminophenol | 0.016 mol/L |
| Sodium metaborate | 0.140 mol/L |
| Sodium hydroxide | 0.360 mol/L |
| Sodium bromide | 0.031 mol/L |
| Potassium metabisulfite | 0.187 mol/L |

The obtained sample A described above was immersed in warm water at 50°° C. for 180 seconds. Then, the sample A was drained with an air shower and allowed to be air-dried.

### Step C1

The sample A treated in Step B1 was transported into a superheated steam treatment bath at 110° C., was left to stand for 30 seconds, and was treated with superheated steam. The steam flow rate at this time was 100 kg/h.

### Step D1

The sample A treated in Step Cl was immersed in a hypochlorous acid containing aqueous solution (25° C.) for 30 seconds. The sample A was taken out from the aqueous solution, was dipped in warm water (liquid temperature: 50° C.) for 120 seconds, and was cleaned. Then, the sample A was drained with an air shower and allowed to be air-dried.

As the hypochlorous acid-containing aqueous solution, a diluted solution prepared by diluting a bleaching agent (trade name “Haiter” manufactured by Kao Corporation) to twice was used.

### Step E1

The sample A obtained in the step E1 was calendered at a pressure of 30 kN using a calendering device including a combination of a metal roller and a resin roller. The calendar processing was carried out at room temperature.

By the above-described step, the underlying silver pattern was formed. The line width and the thickness of the formed underlying silver pattern are shown in the subsequent table. A method for evaluating the line width and the thickness of the underlying silver pattern will be described later.

### Step G1

The liquid negative resist material “ZPN1150” (manufactured by Zeon Corporation) was applied onto substantially the entire surface of the conductive substrate obtained in Step E1 on the side where the underlying silver pattern was formed, to form a resist film (resist film disposing step).

Subsequently, the above-described resist film was irradiated with g-rays having a wavelength of 436 nm from the surface of the base material on the side opposite to the underlying silver pattern side using an ultraviolet exposure device, to expose the resist film using the underlying silver pattern as a self-aligned mask pattern (resist film exposure step). In the exposure treatment, the resist film was exposed to an ultraviolet irradiation amount of 320 mJ/cm², and then subjected to a post-exposure baking (PEB) at 90° C. for 1 minute. After the PEB, the exposed photoresist was subjected to a development treatment using a developer (“NMD-3” manufactured by Tokyo Ohka Kogyo Co., Ltd.) for 1 minute, the non-exposed portion of the resist film was removed, and then the photoresist was washed with water to form a resist pattern (plating resist pattern) (resist developing step), thereby obtaining the sample B including the base material, the underlying silver pattern, and the plating resist pattern.

The shape of the opening portion of the plating resist pattern was substantially the same as the mesh pattern of the underlying silver pattern. In addition, an opening width of the opening portion of the formed plating resist pattern was substantially the same as a line width of the conductive thin wire constituting the mesh pattern of the underlying silver pattern.

### Step H1

The sample B obtained in Step G1 was immersed in a plating liquid A (30° C.) described below. Thereafter, the sample B was taken out from the plating liquid A, and then the sample B was immersed in hot water (liquid temperature: 50° C.) for 120 seconds to be washed, thereby forming a plating film on the underlying silver pattern as the seed layer. In Step H1, the immersion time of the sample B in the plating liquid A was adjusted such that the thickness of the plating film was 2.0 μm.

The composition of the used plating liquid A (total amount of 1,200 mL) is shown below. An addition amount of potassium carbonate (manufactured by FUJIFILM Wako Pure Chemical Corporation) was adjusted such that the pH of the plating liquid A was 9.5. In addition, the following components of the plating liquid A were all used manufactured by FUJIFILM Wako Pure Chemical Corporation.

### Composition of plating liquid A

| | | |
|---|---|---|
| AgNO₃ | 8.8 | g |
| Sodium sulfite | 72 | g |
| Sodium thiosulfate pentahydrate | 66 | g |
| Potassium iodide | 0.004 | g |
| Citric acid | 12 | g |
| Methylhydroquinone | 3.67 | g |

| | |
|---|---|
| Potassium carbonate | predetermined amount |
| Water | remainder |

By the above steps, the conductive substrate of Example 1, including the base material, the conductive thin wire including the underlying silver pattern and the metal pattern consisting of the plating film, and the plating resist pattern formed in the region where the conductive thin wire was not arranged on the base material, was manufactured.

In the manufactured conductive substrate, since the metal density of the underlying silver pattern and the metal density of the plating film were different from each other, each layer was identified with a scanning electron microscope (SEM), and the thickness of each layer and the total thickness could be measured.

Specifically, the conductive substrate was cut along a plane perpendicular to the direction in which the conductive thin wire extended using an ultramicrotome, and a cut cross section including a width direction and a lamination direction (thickness direction) of the conductive thin wire was exposed. Next, as a pre-treatment, carbon having a thickness of 10 to 20 nm was deposited on the exposed cut cross section to produce a test piece for observing a cross section.

An obtained cut cross section of the test piece was observed using an SEM manufactured by Hitachi High-Tech Corporation, thereby obtaining an observation image. The observation conditions were an acceleration voltage of 5 kV and a reflection electron mode. In the observation image, a region in which the element having a large atomic number is included is displayed in white. In the observation image, a white and dense region was defined as a region of the plating film, and a region which was white and was darker than the region of the plating film was defined as a region of the underlying silver pattern, and the thickness was measured. The method of measuring the thickness is as described above.

### EXAMPLES 2 TO 9

In Examples 2 to 9, conductive substrates were manufactured in the same manner as in Example 1, except that the exposure amount was changed by adjusting the exposure time in Step B1 and adjusted such that the line width of the underlying silver pattern was as shown in the table below, or the plating time in Step G1 was changed to perform adjustment such that the plating film thickness was as shown in the table below.

### EXAMPLES 10 AND 11

In Examples 10 and 11, a conductive substrate was manufactured in the same manner as in Example 1, except that, in Step B1, the exposure was performed with a spacer provided between the photosensitive layer and the photo mask. The thickness of the spacer in Example 10 was 4.6 μm, and the thickness of the spacer in Example 11 was 6.0 μm. By changing the above-described procedure, the line width after Step El of Examples 10 and 11 was 2.5 μm.

### EXAMPLE 12

In Example 12, a conductive substrate was manufactured in the same manner as in Example 1, except that, in the plating treatment of Step H1, the following non-electrolytic copper plating liquid was used to perform non-electrolytic copper plating.

As the non-electrolytic copper plating liquid, “OIC ACCERA” and “OIC COPPER” manufactured by OKUNO CHEMICAL INDUSTRIAL CO., LTD. were used. The non-electrolytic copper plating was performed by immersing the above-described sample B in OIC ACCERA (25° C.) for 3 minutes and then in OIC COPPER (55° C.) for 10 minutes, and then rinsing with pure water at 25° C.

### EXAMPLE 13

In Example 13, conductive substrates were manufactured in the same manner as in Example 1, except that the line width of the mask used in Step B1 was changed to be adjusted such that the line width and the thickness of the underlying silver pattern were as shown in the table below, and the plating time in Step G1 was changed such that the plating film thickness was as shown in the table below.

### Example 14

In Example 14, a conductive substrate was manufactured in the same manner as in Example 13, except that the exposure amount in Step B1 was adjusted such that the line width and the thickness of the underlying silver pattern were as shown in the table below, and the plating time in Step G1 was changed to perform adjustment such that the plating film thickness was as shown in the table below.

### EXAMPLE 15

In Example 15, a conductive substrate was manufactured in the same manner as in Example 1, except that the plating time in Step G1 was changed to perform adjustment such that the plating film thickness was as shown in the table below.

### COMPARATIVE EXAMPLES 1 AND 2

Conductive substrates of Comparative Examples 1 and 2 were manufactured according to Example 1 of JP2007-287953A. That is, a metal layer was formed on a base material by sputtering, a negative tone resist film was formed on the metal layer, a resist pattern was formed using the same pattern as in Example 1 of the present invention, a plating film was formed on an opening portion of the resist pattern by electrolytic plating, the resist pattern was removed, and the metal layer formed by sputtering, in which the plating film was not formed, was removed to form a conductive thin wire having a mesh-shaped pattern, thereby manufacturing a conductive substrate. The base material was a polyethylene terephthalate film having a thickness of 40 μm, and the plating film thickness on the underlying metal pattern in Comparative Example 1 was 3 μm, and the plating film thickness in Comparative Example 2 was 6 μm.

### EVALUATION

Hereinafter, the evaluation items, that is, the intersection growing ratio, the line width, the variation in line width, the conductivity, and the visibility will be described.

### Intersection Growing Rate

The intersection growing ratio was obtained by observing the intersection growing with a scanning electron microscope (SEM) to acquire an image, according to the following definition. That is, the angle θ formed by the two conductive thin wires was 90°. A small numerical value of the intersection growing ratio indicates a small degree of growing of the intersection part.

$$( Intersection growing ratio ) = Cw / ( √ 2 \times Lw )$$

The Cw is the same as the diameter Cw of the maximum inscribed circle of the intersection part described above, and is a diameter of the maximum circle inscribed in the intersection part of the conductive thin wire in a case where the conductive substrate is observed from the vertical direction of the film surface. In addition, Lw represents an average line width of the conductive thin wire. The unit of the diameter Cw and the line width Lw of the maximum inscribed circle was μm.

Specifically, the diameter Cw of the maximum inscribed circle was obtained by adopting an average value of maximum diameters of circles inscribed in the five intersection parts, and the Lw was obtained by adopting an average value of line widths of midpoint parts between the intersection parts in a case where the line widths were measured at five points.

### Line Width and Variation in Line Width

The line width W of the conductive thin wire was obtained by observing the film surface of the conductive substrate in a vertical direction using SEM. Specifically, the line width We was obtained by measuring the line widths at five points at equal intervals between the intersections of the conductive thin wires formed in a mesh pattern, and averaging the line widths, the above-described measurement was performed between the intersections of 10 points of the conductive thin wires, and the arithmetic average value of the line widths We obtained at each of the 10 points was defined as the average line width W of the conductive thin wire.

In addition, the variation in line width was obtained by the following expression in a case where the maximum line width was denoted by Wmax, the minimum line width was denoted by Wmin, and the average line width was denoted by W.

$$( Variation in line width ) = \{ ( Wmax - Wmin ) / W \} \times 100 ( \% )$$

The maximum line width Wmax is a value obtained by performing an operation of selecting the maximum line width among the values of the five line widths obtained in a case of measuring the line width We at the above 10 locations and performing an arithmetic average of the obtained 10 values, and the minimum line width Wmin is a value obtained by performing an operation of selecting the minimum line width among the values of the five line widths obtained in a case of measuring the line width We at the above 10 locations and performing an arithmetic average of the obtained 10 values.

It is preferable that the above-described variation in line width is small from the viewpoint that the conductivity shown below is excellent. The variation in line width is preferably 80% or less, more preferably 60% or less, and still more preferably 50% or less. The lower limit of the variation in line width is not particularly limited, and may be 0% or more.

### Conductivity

The surface resistivity was measured at any 10 locations on the surface of the conductive substrate manufactured in each of Examples and Comparative Examples, on which the conductive thin wire was formed, using a resistivity meter (Loresta manufactured by Mitsubishi Chemical Analytech Co., Ltd.: using a series four-needle probe (ASP)). The average value of the surface resistivity obtained by the measurement at 10 locations was defined as the surface resistivity of the conductive substrate. The conductivity of the conductive substrate was evaluated from the average resistivity of the conductive substrate according to the following standard. The evaluation of the conductivity is preferably “B” or more in practical use.
“A”: case where the surface resistivity was less than 10 Ω/□
“B”: case where the surface resistivity was 10 Ω/□ or more and less than 50 Ω/□
“C”: case where the surface resistivity was 50 Ω/□ or more

### Visibility

The obtained conductive substrate was laminated in the order of glass/conductive substrate/polarizing plate 1/polarizing plate 2/black PET (manufactured by Panac Co., Ltd., industrial black PET (GPH100E82A04)) to obtain a laminate. The polarizing plate 1 and the polarizing plate 2 were linear polarizers, and were disposed and laminated such that polarization directions were orthogonal to each other. In addition, the conductive substrate was disposed such that the conductive thin wire side was located on the glass side.

Next, the obtained laminate was visually observed in an environment of 500 lux from the front and an angle of 30° to 60° from the front on the glass surface side. The above observation was performed by 10 observers, and the visibility was evaluated according to the following standard. In a case where the mesh pattern-shaped conductive thin wire is difficult to be visually recognized, the conductive substrate has excellent optical characteristics, and moire generated in a case where the conductive substrate is laminated on the display is reduced. In the evaluation of the visibility, among the following 1 to 5, 3 to 5 are preferable, 4 or 5 is more preferable, and 5 is still more preferable.
5: in a case where the laminate was observed from a position 15 cm away, the number of observers who visually recognized the mesh pattern was 0.
4: in a case where the laminate was observed from a position 30 cm away, the number of observers who visually recognized the mesh pattern was 0 or 1.
3: in a case where the laminate was observed from a position 30 cm away, the number of observers who visually recognized the mesh pattern was 2 to 4.
2: in a case where the laminate was observed from a position 30 cm away, the number of observers who visually recognized the mesh pattern was 5 or more.
1: in a case where the laminate was observed from a position 50 cm away, the number of observers who visually recognized the mesh pattern was 5 or more.

### Result

The evaluation results of each of Examples and each of Comparative Examples are shown in the table.

In the table, “average line width” is a line width (μm) of the conductive thin wire, and is the average line width W of the above-described conductive thin wire.

In the table, “aspect ratio” is a value obtained by dividing the height (μm) of the conductive thin wire by the line width (μm) of the conductive thin wire, and corresponds to a ratio of the height of the conductive thin wire to the line width of the conductive thin wire. The height of the conductive thin wire is a total value of the thickness of the underlying silver pattern and the thickness of the plating film, and the line width of the conductive thin wire is the average line width W of the conductive thin wire.

TABLE 1

| | Thickness | | | | | | | |
|---|---|---|---|---|---|---|---|---|
| | of | | | | | | | |
| | underlying | Thickness | | Variation | | | | |
| | silver | of plating | Average | in line | Aspect ratio | Intersection | | |
| | pattern | film | line width | width | (thickness/line | growing | | |
| | [μm] | [μm] | [μm] | [%] | width) | ratio | Conductivity | Visibility |
| Example 1 | 0.6 | 2.0 | 2.1 | 40 | 1.24 | 1.1 | A | 4 |
| Example 2 | 0.6 | 4.0 | 2.1 | 40 | 2.19 | 1.1 | A | 4 |
| Example 3 | 0.6 | 6.0 | 2.1 | 40 | 3.14 | 1.1 | A | 4 |
| Example 4 | 0.5 | 1.4 | 1.4 | 35 | 1.36 | 1.2 | A | 4 |
| Example 5 | 0.5 | 2.8 | 1.4 | 35 | 2.36 | 1.2 | A | 4 |
| Example 6 | 0.5 | 4.2 | 1.4 | 35 | 3.36 | 1.2 | A | 4 |
| Example 7 | 0.3 | 0.8 | 0.8 | 50 | 1.38 | 1.2 | B | 5 |
| Example 8 | 0.3 | 1.6 | 0.8 | 50 | 2.38 | 1.2 | B | 5 |
| Example 9 | 0.3 | 2.4 | 0.8 | 50 | 3.38 | 1.2 | A | 5 |
| Example 10 | 0.8 | 2.0 | 2.5 | 42 | 1.12 | 1.5 | A | 4 |
| Example 11 | 0.8 | 2.0 | 2.5 | 42 | 1.12 | 1.6 | A | 3 |
| Example 12 | 0.6 | 2.0 | 2.1 | 40 | 1.24 | 1.1 | A | 4 |
| Example 13 | 1.6 | 1.7 | 3.1 | 85 | 1.06 | 1.2 | A | 3 |
| Example 14 | 1.7 | 1.8 | 4.0 | 35 | 0.88 | 1.2 | A | 3 |
| Example 15 | 0.6 | 1.1 | 2.1 | 40 | 0.81 | 1.2 | B | 4 |
| Comparative | 0.1 | 3.0 | 3.0 | 85 | 1.03 | 2.1 | A | 2 |
| Example 1 | | | | | | | | |
| Comparative | 0.1 | 6.0 | 3.0 | 95 | 2.03 | 2.2 | A | 2 |
| Example 2 | | | | | | | | |

From the results in Table 1, it was confirmed that, according to the manufacturing method for a conductive substrate according to the embodiment of the present invention, a conductive substrate having a conductive thin wire with a thin line width and excellent conductivity in which the intersection growing was suppressed could be manufactured. On the other hand, in the conductive substrates of Comparative Examples 1 and 2, which were manufactured by a method other than the manufacturing method for the conductive substrate according to the embodiment of the present invention, the intersection growing could not be suppressed.

From the comparison between Example 13 and the other Examples, it was confirmed that, in a case where the thickness of the underlying silver pattern was 1.0 μm or less, the variation in line width of the formed conductive thin wire was further reduced.

From the comparison between Examples 13 and 14 and Examples 1 to 10 and 12, it was confirmed that, in a case where the line width of the conductive thin wire was 3.0 μm or less, the visibility was more excellent.

From the comparison between Example 15 and Example 1, it was confirmed that, in a case where the ratio of the height of the conductive thin wire to the line width of the conductive thin wire was 1.10 or more, the conductive thin wire was more excellent in conductivity.

From the comparison between Example 11 and the other Examples, it was confirmed that, in a case where the intersection growing ratio was 1.0 to 1.5, the visibility was more excellent.

### EXPLANATION OF REFERENCES

10: base material
12: underlying silver pattern
14: resist film
16: resist pattern
18: metal pattern
20: conductive thin wire
22: underlying silver thin wire
32: non-thin wire portion
22a, 22b: conductive thin wire

What is claimed is:

1. A manufacturing method for a conductive substrate, comprising:
a step of forming a mesh-shaped underlying silver pattern on a side of one surface of a base material by a photographic method;
a step of disposing a resist film on the side of the surface of the base material on which the underlying silver pattern is formed;
a step of exposing the resist film by irradiation of light from a side of a surface of the base material on which the underlying silver pattern is not formed;
a step of developing the exposed resist film to form a resist pattern; and
a step of performing a plating treatment using the underlying silver pattern as a seed layer to form a metal pattern on the underlying silver pattern, thereby obtaining a conductive thin wire.

2. The manufacturing method for a conductive substrate according to claim 1,
wherein an intersection growing ratio of the conductive thin wires is 1.0 to 1.5.

3. The manufacturing method for a conductive substrate according to claim 1,
wherein a line width of the conductive thin wire is 3.0 μm or less.

4. The manufacturing method for a conductive substrate according to claim 2,
wherein a line width of the conductive thin wire is 3.0 μm or less.

5. The manufacturing method for a conductive substrate according to claim 1,
wherein a thickness of the underlying silver pattern is 1.0 μm or less.

6. The manufacturing method for a conductive substrate according to claim 2,
wherein a thickness of the underlying silver pattern is 1.0 μm or less.

7. The manufacturing method for a conductive substrate according to claim 3,
wherein a thickness of the underlying silver pattern is 1.0 μm or less.

8. The manufacturing method for a conductive substrate according to claim 4,
wherein a thickness of the underlying silver pattern is 1.0 μm or less.

9. The manufacturing method for a conductive substrate according to claim 1,
wherein a ratio of a height of the conductive thin wire to a line width of the conductive thin wire is 1.10 or more.

10. The manufacturing method for a conductive substrate according to claim 2,
wherein a ratio of a height of the conductive thin wire to a line width of the conductive thin wire is 1.10 or more.

11. The manufacturing method for a conductive substrate according to claim 3,
wherein a ratio of a height of the conductive thin wire to a line width of the conductive thin wire is 1.10 or more.

12. The manufacturing method for a conductive substrate according to claim 4,
wherein a ratio of a height of the conductive thin wire to a line width of the conductive thin wire is 1.10 or more.

13. The manufacturing method for a conductive substrate according to claim 5,
wherein a ratio of a height of the conductive thin wire to a line width of the conductive thin wire is 1.10 or more.

14. The manufacturing method for a conductive substrate according to claim 6,
wherein a ratio of a height of the conductive thin wire to a line width of the conductive thin wire is 1.10 or more.

15. The manufacturing method for a conductive substrate according to claim 7,
wherein a ratio of a height of the conductive thin wire to a line width of the conductive thin wire is 1.10 or more.

16. The manufacturing method for a conductive substrate according to claim 8,
wherein a ratio of a height of the conductive thin wire to a line width of the conductive thin wire is 1.10 or more.
